(19) United States
(12) Patent Application Publication
(10) Pub. No.: US 2022/0262672 A1
(43) Pub. Date: Aug. 18, 2022

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventor: Yutaka UCHIDA, Matsumoto-city (JP)

(21) Appl. No.: 17/645,991

(22) Filed: Dec. 26, 2021

(30) Foreign Application Priority Data
Feb. 18, 2021 (JP) 2021-023946

(51) Int. Cl. H01L 21/762; H01L 29/06; H01L 29/40

(52) U.S. Cl. CPC H01L 21/76224; H01L 29/402; H01L 29/0623

(57) ABSTRACT

Provided is a semiconductor device including: a semiconductor substrate having a substrate upper surface; and an embedded oxide film provided in the substrate upper surface and at least partially embedded below the substrate upper surface. An upper surface of the embedded oxide film has an end portion and a central portion in a direction parallel to the substrate upper surface. The end portion of the upper surface of the embedded oxide film is disposed at the same height position as the substrate upper surface or below the substrate upper surface. The central portion of the upper surface of the embedded oxide film is disposed at a position higher than the end portion of the upper surface.

The contents of the following Japanese patent application are incorporated herein by reference:
No. 2021-023946 filed in JP on Feb. 18, 2021

### BACKGROUND

### 1. Technical Field

The present invention relates to a semiconductor device and a manufacturing method of the semiconductor device.

### 2. Related Art

Conventionally, a configuration in which an embedded oxide film is provided in an upper surface of a semiconductor substrate on which a semiconductor device such as an IGBT is formed is known (see, for example, Patent Documents 1 and 2).
Patent Document 1: Japanese Patent Application Publication No. 2017-143136
Patent Document 2: Japanese Patent Application Publication No. H5-206263

### SUMMARY

### Technical Problem

A protruding portion called a bird's beak may be formed in an end portion of the embedded oxide film. The length or thickness of the bird's beak is preferably small.

### Technical Solution

A first aspect of the present invention provides a semiconductor device. The semiconductor device may include a semiconductor substrate having a substrate upper surface. The semiconductor device may include an embedded oxide film provided on the substrate upper surface and at least partially embedded below the substrate upper surface. The upper surface of the embedded oxide film may have an end portion and a central portion in a direction parallel to the substrate upper surface. The end portion of the upper surface of the embedded oxide film may be disposed at the same height position as the substrate upper surface or below the substrate upper surface. The central portion of the upper surface of the embedded oxide film may be disposed at a position higher than the end portion of the upper surface.

The central portion of the upper surface of the embedded oxide film may be a portion disposed at the highest position in the embedded oxide film.

The central portion of the upper surface of the embedded oxide film may be disposed at the same height as the substrate upper surface.

The upper surface of the embedded oxide film may have a flat region that is flat and includes a central portion.

The upper surface of the embedded oxide film may have a convex portion protruding downward in a region disposed below the substrate upper surface.

The semiconductor substrate may have a recess portion in which the embedded oxide film is embedded. The depth of the lowermost portion disposed on the lowermost side of the upper surface of the embedded oxide film from the substrate upper surface may be 20% or less of the depth of the recess portion from the substrate upper surface.

The semiconductor substrate may have a recess portion in which the embedded oxide film is embedded. The height of the central portion of the upper surface of the embedded oxide film from the substrate upper surface may be 20% or less of the depth of the recess portion from the substrate upper surface.

The semiconductor substrate may have a recess portion in which the embedded oxide film is embedded. The average value of the height of the upper surface of the embedded oxide film from the substrate upper surface may be 20% or less of the depth of the recess portion from the substrate upper surface.

A second aspect of the present invention provides a manufacturing method of a semiconductor device. The manufacturing method may include a recess portion forming step of forming a recess portion on the substrate upper surface of the semiconductor substrate. The manufacturing method may include an oxide film forming step of forming an oxide film covering a range wider than the recess portion on the substrate upper surface. The manufacturing method may include an etching step of selectively removing the oxide film covering at least the end portion of the recess portion by wet etching for forming an embedded oxide film at least a part of which is formed in the recess portion.

In the oxide film forming step, an oxide film may be formed throughout the substrate upper surface.

In the oxide film forming step, a concave portion may be formed in the upper surface of the oxide film at a position overlapping the recess portion. The manufacturing method may include a resist applying step of applying the upper surface of the oxide film with a resist in a range wider than the concave portion after the oxide film forming step. The manufacturing method may include a resist removing step of removing the resist in a region other than the concave portion before the etching step. In the etching step, the oxide film may be wet etched using the resist in the concave portion as a mask.

In the resist applying step, the thickness of the resist formed in the concave portion may be larger than the thickness of the resist formed in the region other than the concave portion.

In the resist removing step, the entire surface of the resist may be exposed, and the entire surface of the resist may be immersed in a developer. In the resist removing step, the entire surface of the resist may be exposed. In the resist removing step, a negative resist may be used as the resist.

The recess portion may have an end portion in a direction parallel to the substrate upper surface. In the etching step, the oxide film may be wet etched until the oxide film in the end portion of the recess portion has a height equal to or lower than a height of the substrate upper surface.

The manufacturing method may include an impurity forming step in which impurities are implanted from the substrate upper surface to form a local impurity region on the upper surface side of the semiconductor substrate. The recess portion forming step, the oxide film forming step, and the etching step may be performed before the impurity forming step.

The summary clause does not necessarily describe all necessary features of the embodiments of the present invention. The present invention may also be a sub-combination of the features described above.

### BRIEF DESCRIPTION OF THE DRAWINGS

FIG. 1 is a top view illustrating an outline of a semiconductor device 100 according to an embodiment of the present invention.

FIG. 2 is a diagram illustrating a cross section taken along line A-A′ in FIG. 1.

FIG. 3 is a diagram illustrating a method for forming an embedded oxide film 124 according to a comparative example.

FIG. 4 is a diagram illustrating a method for forming an embedded oxide film 24 according to an example.

FIG. 5 is an enlarged view of the embedded oxide film 24 and a recess portion 72.

FIG. 6 is a diagram illustrating another example of the embedded oxide film 24.

FIG. 7 is a diagram illustrating another example of the embedded oxide film 24.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to the solution of the invention. It is preferable that the same or equivalent description includes up to 5% in consideration of variations in manufacturing.

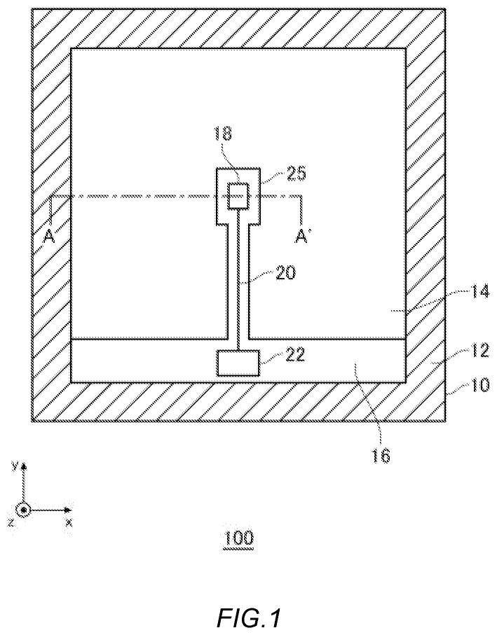

FIG. 1 is a top view illustrating an outline of a semiconductor device 100 according to an embodiment of the present invention. The semiconductor device 100 includes a semiconductor substrate 10 made of silicon or the like. In the present specification, two orthogonal axes parallel to the upper surface (in this specification, it may be referred to as a substrate upper surface) of the semiconductor substrate 10 are defined as an x axis and a y axis, and an axis perpendicular to the upper surface is defined as a z axis. The semiconductor substrate 10 has an active region 14 and a withstand voltage structure portion 12. In the active region 14, at least one of a transistor such as an insulated gate bipolar transistor (IGBT) and a diode such as a freewheeling diode (FWD) is formed. An electrode such as an emitter electrode, an dielectric film that insulates each electrode from the semiconductor substrate 10, and the like are provided above the active region 14, but are omitted in FIG. 1.

In the active region 14 of the present example, a diode 18 for temperature detection is provided. However, the diode 18 may not be provided. The diode 18 of the present example is disposed near the center of the active region 14. The diode 18 is provided on the dielectric film 25. At least a part of the dielectric film 25 is embedded in the semiconductor substrate 10 in the upper surface of the semiconductor substrate 10.

The withstand voltage structure portion 12 is provided so as to surround the active region 14. The withstand voltage structure portion 12 is provided farther outward in the semiconductor substrate 10 with respect to the diode 18 and the active region 14. The withstand voltage structure portion 12 of the present example is provided along an edge of the semiconductor substrate 10 in a top view. The withstand voltage structure portion 12 includes a guard ring, a field plate, or the like, and suppresses concentration of an electric field at a terminal portion of the active region 14 to improve the withstand voltage of the semiconductor device 100.

In addition, a pad region 16 is provided in the upper surface of the semiconductor substrate 10. In the pad region 16, a pad 22 connected to the diode 18 and a pad connected to a semiconductor device or the like provided in the active region 14 may be formed. For example, in the pad region 16, a gate pad connected to a gate terminal of a transistor provided in the active region 14 is formed. The pad 22 may be connected to the diode 18 by a wiring 20. Although the pad 22 and the wiring 20 are provided for each cathode and anode of the diode 18, only a set of the pad 22 and the wiring 20 is schematically illustrated in FIG. 1.

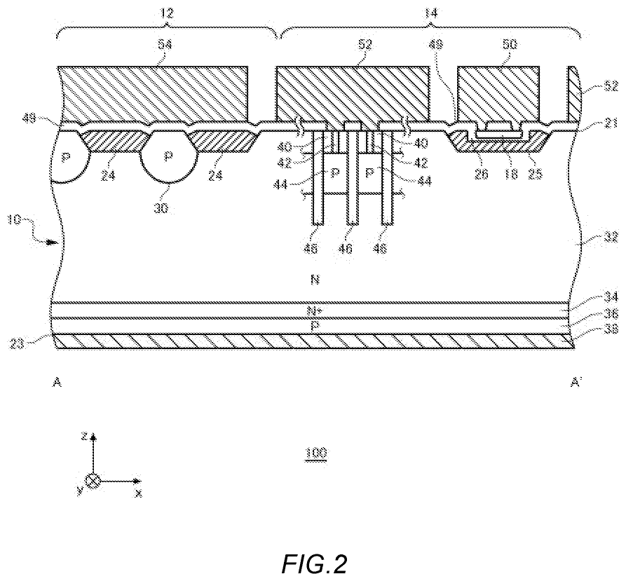

FIG. 2 illustrates a cross section taken along a line A-A′ in FIG. 1. The A-A′ cross section is an xz plane passing through the withstand voltage structure portion 12, the active region 14, and the diode 18. However, in FIG. 2, a part of the withstand voltage structure portion 12 is omitted.

The semiconductor substrate 10 has an upper surface 21 and a lower surface 23. In the present example, the semiconductor substrate 10 is an N type (or N− type) substrate. At least a part of a semiconductor device such as an IGBT is formed in the upper surface 21 of the semiconductor substrate 10. A partial region of the semiconductor substrate 10 functions as a drift region 32 where carriers move between the upper surface 21 and the lower surface 23. In the example of FIG. 2, an IGBT including a plurality of gate trenches 46 is formed in the active region 14.

In a mesa portion between two adjacent gate trenches 46, an N+ type emitter region 40, a P type base region 44, and an N type drift region 32 are formed in order from the upper surface 21 side of the semiconductor substrate 10. On the lower surface 23 side of the semiconductor substrate 10, an N+ type field stop layer 34, a P type collector layer 36, and a collector electrode 38 are formed under the drift region 32.

A P+ type contact region 42 may be formed in a part of the emitter region 40. The contact region 42 is formed from the upper surface 21 of the semiconductor substrate 10 to the base region 44. An emitter electrode 52 is provided above the upper surface 21 of the semiconductor substrate 10. An interlayer dielectric film 49 is formed between the gate trench 46 and the emitter electrode 52 to insulate both from each other. In addition, in the interlayer dielectric film 49, a contact hole for exposing the emitter region 40 and the contact region 42 is formed in each mesa portion. The emitter electrode 52 is electrically connected to the emitter region 40 and the contact region 42 via the contact hole.

A groove 26 may be formed on the upper surface of the dielectric film 25. The groove 26 is a recess provided so as not to penetrate the dielectric film 25. The diode 18 may be disposed in the groove 26. The entire diode 18 may be formed inside the groove 26, or a part thereof may be formed inside the groove 26.

The upper surface of the diode 18 is covered with the interlayer dielectric film 49. The interlayer dielectric film 49 is, for example, silicate glass doped with impurities such as boron or phosphorus, but is not limited thereto. The interlayer dielectric film 49 is provided with a contact hole that connects a diode electrode 50 and the diode 18. The diode electrode 50 is connected to the pad 22 via the wiring 20. The diode electrode 50 is provided for each of the cathode and the anode.

One or more embedded oxide films 24 may be formed in the withstand voltage structure portion 12. One or more embedded oxide films 24 may also be formed in the active region 14. As described above, at least a part of the embedded oxide film 24 is embedded in the semiconductor substrate 10. That is, at least a part of the embedded oxide film 24 is disposed below the upper surface 21 of the semiconductor substrate 10. The upper surface 21 of the semiconductor substrate 10 is a surface disposed on the uppermost side among the surfaces of the semiconductor substrate 10. In the present specification, a thickness direction (z axis direction) of the semiconductor substrate 10 is defined as a vertical direction. In addition, in the semiconductor substrate 10, a surface on which a gate electrode and an emitter region (or a source region) of a transistor or an anode region of a diode is provided is defined as the upper surface 21, and a surface on which a collector region (or a drain region) of a transistor or a cathode region of a diode is provided is defined as the lower surface 23.

In the withstand voltage structure portion 12 of the present example, one or more embedded oxide films 24 are locally formed. A P type guard ring 30 may be formed between the two embedded oxide films 24 adjacent to each other. The guard ring 30 is in contact with the upper surface 21 of the semiconductor substrate 10. The interlayer dielectric film 49 may be formed on the embedded oxide film 24 and the guard ring 30. An electrode 54 may be formed on the interlayer dielectric film 49. The electrode 54 may be electrically connected to the guard ring 30. A field plate may be provided on the embedded oxide film 24.

In the embedded oxide film 24 of the present example, the height position of the end portion in the xy plane is the same as that of the upper surface 21 of the semiconductor substrate 10 or lower than that of the upper surface 21. In the embedded oxide film 24, the height position of the central portion in the xy plane is higher than that of the end portion. With such a structure, a bird's beak at the end portion of the embedded oxide film 24 can be reduced, and the end portion of the embedded oxide film 24 can be suppressed from protruding from the upper surface 21 of the semiconductor substrate 10.

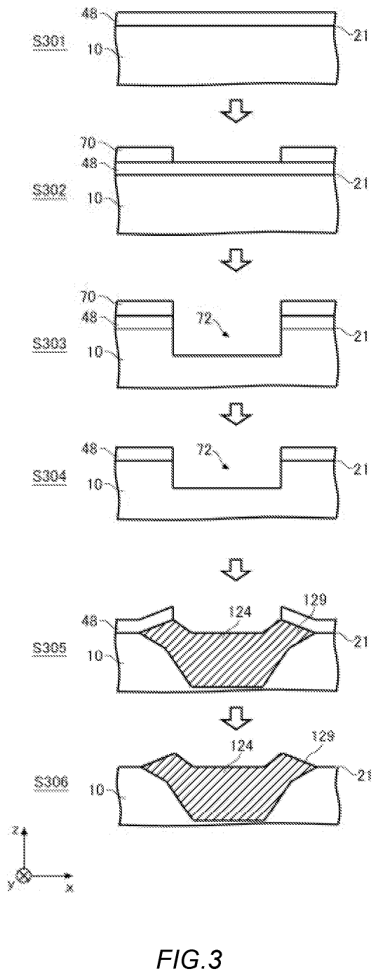

FIG. 3 is a diagram illustrating a method for forming an embedded oxide film 124 according to a comparative example. In the comparative example, first, the entire upper surface 21 of the semiconductor substrate 10 is nitrided to form a nitride film 48 (S301). Next, a resist film 70 having a predetermined pattern is formed on the upper surface of the nitride film 48 by lithography (S302).

Next, using the resist film 70 as a mask, the nitride film 48 and the semiconductor substrate 10 are etched to form the recess portion 72 (S303). Next, the resist film 70 is removed (S304).

Next, the semiconductor substrate 10 is thermally oxidized to form embedded oxide film 124 in the recess portion 72 (S305). The semiconductor substrate 10 is covered with the nitride film 48 except for the recess portion 72. Thus, the embedded oxide film 124 can be selectively formed in the recess portion 72. However, since the oxidation of the semiconductor substrate 10 also proceeds from the side surface of the recess portion 72, the embedded oxide film 124 is also formed in the region covered with the nitride film 48 at the end portion of the recess portion 72. As a result, a bird's beak 129 protruding upward is formed at the end portion of the embedded oxide film 124.

Next, the nitride film 48 is removed (S306). Even if the nitride film 48 is removed, the bird's beak 129 remains. Therefore, in the embedded oxide film 124, the end portion protrudes upward from the upper surface 21 of the semiconductor substrate 10.

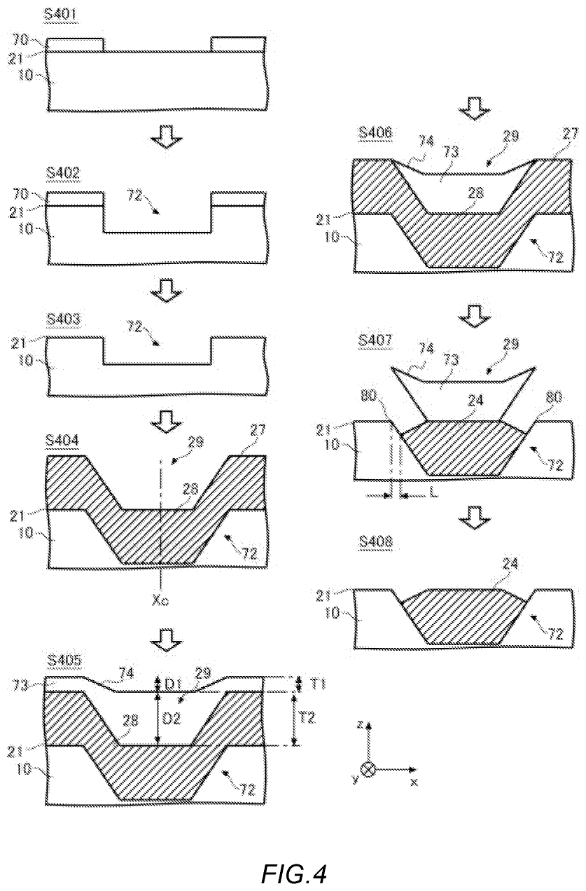

FIG. 4 is a diagram illustrating a method for forming the embedded oxide film 24 according to an example. The manufacturing method of the semiconductor device 100 includes a forming step illustrated in FIG. 4. In the example, in a resist film forming step S401, the resist film 70 having a predetermined pattern is formed in the upper surface 21 of the semiconductor substrate 10. In Step S401, the resist film 70 may be patterned by lithography or the like. The resist film 70 may be in contact with the upper surface 21 of the semiconductor substrate 10. Note that the semiconductor substrate 10 may have a thin oxide film on the upper surface 21. The thickness of the oxide film is, for example, 100 nm or less. In a case where an oxide film of 100 nm or less is formed on the surface of the semiconductor substrate 10 in contact with a semiconductor material such as silicon, the oxide film is included in the semiconductor substrate 10 in the present specification.

Next, in a recess portion forming step S402, the semiconductor substrate 10 is etched using the resist film 70 as a mask to form the recess portion 72 in the semiconductor substrate 10. In the recess portion forming step S402, the recess portion 72 may be formed by isotropic etching, or the recess portion 72 may be formed by anisotropic etching. A depth of the recess portion 72 may be, for example, 1 μm. Next, in a resist removal step S403, the resist film 70 is removed.

Next, in an oxide film forming step S404, an oxide film 28 covering a range wider than the recess portion 72 is formed on the upper surface 21 of the semiconductor substrate 10. In the top view of the semiconductor substrate 10, the oxide film 28 may cover a range of twice or more of the area of the recess portion 72, or may cover the entire upper surface 21 of the semiconductor substrate 10. In the oxide film forming step S404, the oxide film 28 may be formed by thermally oxidizing the upper surface 21 of the semiconductor substrate 10. The thickness of the oxide film 28 may be, for example, 1 μm in order to obtain the withstand voltage of the withstand voltage structure portion 12.

In the upper surface of oxide film 28 in the present example, a concave portion 29 is formed at a position overlapping the recess portion 72. In the oxide film forming step S404, the oxide film 28 may be formed such that the upper surface of the oxide film 28 is at the same height as the upper surface 21 of the semiconductor substrate 10 at the center Xc of the recess portion 72 in the x axis direction. In another example, at the center Xc of the recess portion 72, the difference between the thickness of the oxide film 28 and the depth of the recess portion 72 may be less than or equal to 20% of the depth of the recess portion 72.

Next, in a resist applying step S405, a resist is applied to an upper surface 27 of the oxide film 28 in a range wider than the concave portion 29 to form a resist film 73. The resist film 73 may be provided in a range of twice or more of the area of the concave portion 29 in the top view of the semiconductor substrate 10, or may be provided throughout the upper surface 27 of the oxide film 28.

The resist used in the resist applying step S405 is preferably a planer type in which the upper surface is likely to be flat. That is, it is preferable to use a resist material having a relatively low viscosity. In the upper surface of the resist film 73, a step 74 may be provided at a position overlapping the concave portion 29. A depth D1 of the step 74 in the z axis direction is smaller than a depth D2 of the concave portion 29. These depths may be measured at the center Xc of the recess portion 72. The depth D1 may be less than or equal to a half of the depth D2, or may be less than or equal to ¼. The depth D1 may be 0. A thickness T2 of the resist film 73 formed in the concave portion 29 is larger than a thickness T1 of the resist film 73 formed in a region other than the concave portion 29. The thickness T2 may be measured at the center Xc of the recess portion 72. As the thickness T1, an average value of the thicknesses of the resist film 73 in a region not overlapping the concave portion 29 may be used. The thickness T2 may be twice or more, or four times or more of the thickness T1. The thickness T1 may be the same as or different from the depth D1. The thickness T2 may be the same as or different from the depth D2.

Next, in a resist removing step S406, the resist film 73 in the region other than the concave portion 29 is removed. In the resist removing step S406, the resist film 73 is removed so that the upper surface 27 of the oxide film 28 in the region other than the concave portion 29 is exposed. In the resist removing step S406, the film thickness of the resist film 73 is reduced throughout the entire resist film 73. The reduction width of the film thickness is preferably uniform over the entire resist film 73, but may vary. For example, the reduction width of the film thickness may have a variation of ±10% or less.

Since the entire film thickness of the resist film 73 is reduced by a substantially uniform reduction width, the resist film 73 can be formed in the concave portion 29 by self-alignment without exposing a specific pattern to the resist film 73. Further, the resist film 73 can be formed above the recess portion 72 without positional displacement.

As an example, in a case where the resist film 73 is a negative resist, the entire surface of the resist film 73 is exposed under a predetermined condition in the resist removing step S406. In the resist removing step S406, the entire resist film 73 may be exposed under the same condition. The exposure conditions are, for example, exposure time and intensity of irradiation light. In the resist removing step S406, the exposure condition may be adjusted for each region of the resist film 73 so as to reduce the variation in the reduction width of the film thickness of the resist film 73. For example, the exposure condition for each region may be adjusted according to the film thickness in each region of the resist film 73. After the exposure, the entire surface of the resist film 73 is immersed in a developer. Accordingly, the resist film 73 covering above the recess portion 72 can be formed. By exposing the negative resist to light and then immersing the negative resist in a developer, it is easy to form the resist film 73 that covers above the recess portion 72 as compared with a case where the negative resist is immersed in the developer without being exposed. The resist film 73 covers at least the center Xc of the recess portion 72. The resist film 73 may cover the entire recess portion 72. In a case where the resist film 73 is a positive resist, the exposure of the resist film 73 may be omitted, and the resist film 73 may be immersed in a developer.

Next, in an etching step S407, oxide film 28 covering at least an end portion 80 of the recess portion 72 is selectively removed. This forms the embedded oxide film 24 at least partially formed in the recess portion 72. The end portion 80 is an end of the recess portion 72 in a direction parallel to the upper surface 21. This can reduce or eliminate the bird's beak at the end portion of the embedded oxide film 28.

In the etching step S407, the oxide film 28 is wet etched using the resist film 73 in the concave portion 29 as a mask. Accordingly, the oxide film 28 in the region other than the recess portion 72 is removed. Since the etching solution enters between the resist film 73 and the semiconductor substrate 10, a part of the oxide film 28 formed near the end portion 80 of the recess portion 72 is also removed. The etching solution is, for example, a diluted hydrofluoric acid solution, but is not limited thereto.

In the etching step S407, the oxide film 28 is wet etched until the oxide film 28 at the end portion 80 is at the same height as the upper surface 21 or lower than the upper surface 21. In the etching step S407, the oxide film 28 is etched so that the end portion 80 is exposed. In the etching step S407, the oxide film 28 may be etched such that the side wall of the recess portion 72 is exposed in the range of a distance L from the end portion 80. The distance L is a distance on the xy plane. The distance L may be greater than 0, 0.5 μm or more, or 1 μm or more. The distance L may be 1% or more or 5% or more of the width of the recess portion 72 in the xy plane.

Next, in a resist removing step S408, the resist film 73 remaining in the upper surface of the embedded oxide film 24 is removed. Consequently, the embedded oxide film 24 embedded in the recess portion 72 can be formed.

Note that the manufacturing method of the semiconductor device 100 further includes an impurity forming step in which impurities are implanted from the upper surface 21 of the semiconductor substrate 10 to form a local impurity region on the upper surface 21 side of the semiconductor substrate 10. The impurity region is, for example, the emitter region 40, the base region 44, and the contact region 42 described in FIG. 2. The steps from S401 to S408 described in FIG. 4 are preferably performed before the impurity forming step. This makes it possible to reduce the influence of the steps from S401 to S408 on the impurity region. The steps from S401 to S408 are preferably performed before the step of forming the field stop layer 34 and the collector layer 36.

In the example of FIG. 4, the embedded oxide film 24 can be formed without forming a nitride film. Therefore, the number of film forming steps is reduced, and the manufacturing cost can be reduced.

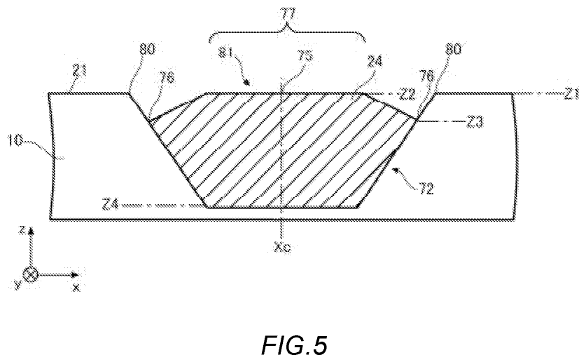

FIG. 5 is an enlarged view of the embedded oxide film 24 and the recess portion 72. As described above, at least a part of the embedded oxide film 24 is formed in the recess portion 72. That is, at least a part of the embedded oxide film 24 is embedded below the upper surface 21 of the semiconductor substrate 10.

Of the surfaces of the embedded oxide film 24, a surface observed as viewed from above is defined as an upper surface 81. That is, the surface exposed upward is defined as the upper surface 81. The upper surface 81 of the embedded oxide film 24 has an end portion 76 and a central portion 75. The end portion 76 is the end of the upper surface 81 in a direction parallel to the upper surface 21, and the central portion 75 is a center of the upper surface 81 in the direction. The position of the central portion 75 may be the same as the center Xc of the recess portion 72.

The height position of the end portion 76 of the upper surface 81 of the embedded oxide film 24 is defined as Z3, and the height position of the central portion 75 is defined as Z2. The height position of the upper surface 21 of the semiconductor substrate 10 is defined as Z1. The height position of a lower end of recess portion 72 is defined as Z4. The height position is a position in the z axis direction. The height position Z3 may be the same as the height position Z1, and may be disposed below the height position Z1. The below or the lower side refers to a side close to the lower surface 23 of the semiconductor substrate 10.

The end portion 76 is disposed at the same height position as the upper surface 21 or below the upper surface 21. In the upper surface 81 of the embedded oxide film 24, the portion disposed on the lowermost side is referred to as a lowermost portion. In the example of FIG. 5, the end portion 76 is the lowermost portion. A depth (Z1−Z3 in the present example) of the lowermost portion with respect to the upper surface 21 may be 20% or less, 10% or less, or 5% or less of the depth (Z1−Z4 in the present example) of the recess portion 72. This makes it possible to reduce the step between the upper surface 81 and the upper surface 21 of the embedded oxide film 24.

The central portion 75 of the upper surface 81 of the embedded oxide film 24 is disposed above the end portion 76. The central portion 75 may be a portion disposed at the highest position in the embedded oxide film 24. The height position Z2 of the central portion 75 may be the same as or different from the height position Z1 of the upper surface 21 of the semiconductor substrate 10. The height or the depth (|Z1−Z2| in the present example) of the central portion 75 from the upper surface 21 may be 20% or less, 10% or less, or 5% or less of the depth (Z1−Z4 in the present example) of the recess portion 72 from the upper surface 21. |Z1−Z2| may be smaller than Z1−Z3. This makes it possible to reduce the step between the upper surface 81 and the upper surface 21 of the embedded oxide film 24.

The height position of the upper surface 81 of the embedded oxide film 24 may continuously increase from the lowermost portion to the central portion 75. The continuous increase means that there is no region where the height position of the upper surface 81 decreases in the process from the lowermost portion toward the central portion 75. The height position of the upper surface 81 of the embedded oxide film 24 may continuously increase from the end portion 76 to the central portion 75.

The average value of the height or depth of the upper surface 81 of embedded oxide film 24 from upper surface 21 may be 20% or less, 10% or less, or 5% or less of the depth (Z1−Z4) of the recess portion 72. The average value is an average value of distances between the upper surface 81 and the upper surface 21 in the z axis direction. This makes it possible to reduce the step between the upper surface 81 and the upper surface 21 of the embedded oxide film 24.

The upper surface 81 of the embedded oxide film 24 may have a flat region 77 that is flat and includes the central portion 75. The flat region 77 may be completely flat, and may have minute concave and convex portions that can be regarded as substantially flat. The size of the concave and convex portions in the z axis direction may be 1 μm or less, 0.5 μm or less, or 0.1 μm or less. The flat region 77 may have a length of 10% or more, a length of 30% or more, or a length of 50% or more of the width of the recess portion 72 in the x axis direction. The width of the recess portion 72 is the width of the opening of the recess portion 72 in the upper surface 21. According to the process illustrated in FIG. 4, the relatively large flat region 77 can be easily formed. Therefore, the flatness of the upper surface 81 of the embedded oxide film 24 can be improved.

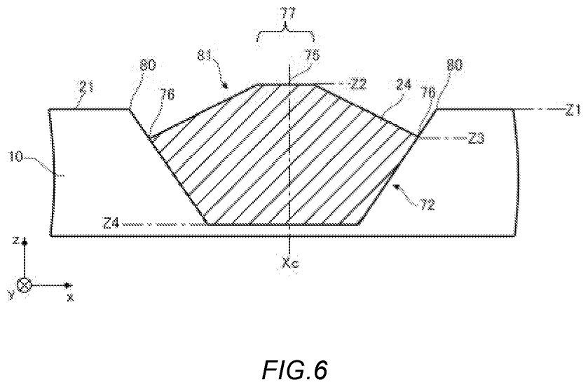

FIG. 6 is a diagram illustrating another example of the embedded oxide film 24. In the present example, the central portion 75 of the upper surface 81 of the embedded oxide film 24 is disposed above the upper surface 21 of the semiconductor substrate 10. Also in the present example, each of the height positions Z1, Z2, Z3, and Z4 may satisfy the same condition as the example described in FIG. 5. In another example, the central portion 75 may be disposed below the upper surface 21 of the semiconductor substrate 10. Also in this case, each of the height positions Z1, Z2, Z3, and Z4 may satisfy the same condition as the example described in FIG. 5.

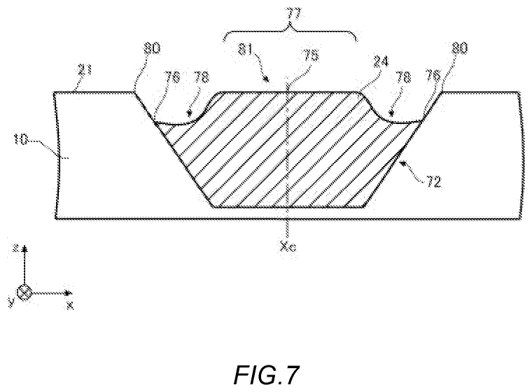

FIG. 7 is a diagram illustrating another example of the embedded oxide film 24. The upper surface 81 of the embedded oxide film 24 of the present example has a convex portion 78 which protrudes downward in a region disposed below the upper surface 21 of the semiconductor substrate 10. The convex portion 78 is disposed between the end portion 76 and the flat region 77. As described with reference to FIG. 4, since the oxide film 28 near the end portion 80 of the recess portion 72 is etched by wet etching, the convex portion 78 is easily formed near the end portion 76 of the embedded oxide film 24. The end portion 76 may be disposed at an end of the convex portion 78. By providing the convex portion 78, the angle of the upper surface 81 in the vicinity of the end portion 76 can be made close to the angle of the side wall of the recess portion 72. This makes it easy to form other members such as the electrode 54 above the end portion 76.

While the present invention has been described using the embodiments, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: semiconductor substrate
12: withstand voltage structure portion
14: active region
16: pad region
18: diode
20: wiring
21: upper surface
22: pad
23: lower surface
24: embedded oxide film
25: dielectric film
26: groove
27: upper surface
28: oxide film
29: concave portion
30: guard ring
32: drift region
34: field stop layer
36: collector layer
38: collector electrode
40: emitter region
42: contact region
44: base region
46: gate trench
48: nitride film
49: interlayer dielectric film
50: diode electrode
52: emitter electrode
54: electrode
70: resist film
72: recess portion
73: resist film
74: step
75: central portion
76: end portion
77: flat region
78: convex portion
80: end portion
81: upper surface
100: semiconductor device
124: embedded oxide film
129: bird's beak

What is claimed is:

1. A semiconductor device comprising:
a semiconductor substrate having a substrate upper surface; and
an embedded oxide film provided in the substrate upper surface and at least partially embedded below the substrate upper surface,
wherein an upper surface of the embedded oxide film has an end portion and a central portion in a direction parallel to the substrate upper surface,
wherein the end portion of the upper surface of the embedded oxide film is disposed at the same height position as that of the substrate upper surface or below that of the substrate upper surface, and
wherein the central portion of the upper surface of the embedded oxide film is disposed at a position higher than the end portion of the upper surface.

2. The semiconductor device according to claim 1,
wherein the central portion of the upper surface of the embedded oxide film is a portion disposed at a highest position in the embedded oxide film.

3. The semiconductor device according to claim 1,
wherein the central portion of the upper surface of the embedded oxide film is disposed at the same height as the substrate upper surface.

4. The semiconductor device according to claim 1,
wherein the upper surface of the embedded oxide film has a flat region, and the flat region is flat and includes the central portion.

5. The semiconductor device according to claim 1,
wherein the upper surface of the embedded oxide film has a convex portion protruding downward in a region disposed below the substrate upper surface.

6. The semiconductor device according to claim 1,
wherein the semiconductor substrate has a recess portion in which the embedded oxide film is embedded, and
wherein a depth of a lowermost portion of the upper surface of the embedded oxide film, which is disposed on a lowermost side, from the substrate upper surface is 20% or less of a depth of the recess portion from the substrate upper surface.

7. The semiconductor device according to claim 1,
wherein the semiconductor substrate has a recess portion in which the embedded oxide film is embedded, and
wherein a height of the central portion of the upper surface of the embedded oxide film from the substrate upper surface is 20% or less of a depth of the recess portion from the substrate upper surface.

8. The semiconductor device according to claim 1,
wherein the semiconductor substrate has a recess portion in which the embedded oxide film is embedded, and
wherein an average value of heights of the upper surface of the embedded oxide film from the substrate upper surface is 20% or less of a depth of the recess portion from the substrate upper surface.

9. The semiconductor device according to claim 4,
wherein the central portion of the upper surface of the embedded oxide film is a portion disposed at a highest position in the embedded oxide film.

10. The semiconductor device according to claim 4,
wherein the central portion of the upper surface of the embedded oxide film is disposed at the same height as the substrate upper surface.

11. The semiconductor device according to claim 4,
wherein the upper surface of the embedded oxide film has a convex portion protruding downward in a region disposed below the substrate upper surface.

12. A manufacturing method of a semiconductor device, the method comprising:
forming a recess portion on a substrate upper surface of a semiconductor substrate;
forming an oxide film covering a range wider than the recess portion in the substrate upper surface; and
selectively removing the oxide film covering at least an end portion of the recess portion by wet etching to form an embedded oxide film at least a part of which is formed in the recess portion.

13. The manufacturing method of a semiconductor device according to claim 12,
wherein the oxide film is formed throughout the substrate upper surface in the forming of the oxide film.

14. The manufacturing method of a semiconductor device according to claim 12,
wherein, in the forming of the oxide film, a concave portion is formed in an upper surface of the oxide film at a position overlapping the recess portion,
the manufacturing method further comprising:
applying a resist to a range wider than the concave portion in the upper surface of the oxide film after the forming of the oxide film; and
removing the resist of a region other than the concave portion before the etching,
wherein, in the etching, the oxide film is wet etched using the resist in the concave portion as a mask.

15. The manufacturing method of a semiconductor device according to claim 14,
wherein, in the applying of the resist, a thickness of the resist formed in the concave portion is larger than a thickness of the resist formed in a region other than the concave portion.

16. The manufacturing method of a semiconductor device according to claim 14,
wherein, in the removing of the resist, an entire surface of the resist is immersed in a developer.

17. The manufacturing method of a semiconductor device according to claim 16,
wherein the entire surface of the resist is exposed in the removing of the resist.

18. The manufacturing method of a semiconductor device according to claim 17,
wherein, in the removing of the resist, a negative resist is used as the resist.

19. The manufacturing method of a semiconductor device according to claim 14,
wherein the recess portion has an end portion in a direction parallel to the substrate upper surface, and
wherein, in the etching, the oxide film is wet etched until the oxide film in the end portion of the recess portion has a height equal to or lower than a height of the substrate upper surface.

20. The manufacturing method of a semiconductor device according to claim 12, further comprising:
implanting impurities from the substrate upper surface for forming a local impurity region on an upper surface side of the semiconductor substrate,
wherein the forming of the recess portion, the forming of the oxide film, and the etching are performed before the forming of the impurity region.
